(19) United States
(12) Patent Application Publication
(10) Pub. No.: US 2026/0190888 A1
(43) Pub. Date: Jul. 2, 2026

(54) ETCHING METHOD AND PLASMA PROCESSING APPARATUS

(71) Applicant: Tokyo Electron Limited, Tokyo (JP)

(72) Inventors: Fumiya TAKATA, Hsin-chu City (TW); Shinya MORIKITA, Miyagi (JP); Kota OIKAWA, Miyagi (JP); Natsuki NIIKURA, Miyagi (JP)

(73) Assignee: Tokyo Electron Limited, Tokyo (JP)

(21) Appl. No.: 19/552,566

(22) Filed: Feb. 27, 2026

Related U.S. Application Data
(63) Continuation of application No. PCT/JP2024/031742, filed on Sep. 4, 2024.

(30) Foreign Application Priority Data
Sep. 8, 2023 (JP) 2023-145733

(51) Int. Cl. H10P 50/28; H01J 37/32; H10P 50/00; H10P 72/00

(52) U.S. Cl. CPC H10P 50/283; H01J 37/32174; H10P 50/73; H10P 72/0421; H01J 2237/3346

(57) ABSTRACT

An etching method including: (a) preparing a substrate on a substrate support disposed in a chamber of a plasma processing apparatus, the substrate including a first film and a second film, the first film containing silicon and nitrogen, and the second film containing silicon and oxygen; (b) supplying a processing gas into the chamber; and (c) while the (b) is being executed, selectively etching the second film with respect to the first film, the (c) including (c1) forming a plasma by setting a power of a source RF signal having a first frequency to a first power, and supplying a first bias signal to the substrate support with a second power, the first bias signal having a frequency lower than the first frequency, and (c2) after the (c1), supplying the first bias signal to the substrate support with a third power higher than the second power.

### CROSS-REFERENCE TO RELATED APPLICATIONS

The present application is a bypass continuation application of PCT Application No. PCT/JP 2024/031742 filed on Sep. 4, 2024, which claims priority under 35 U.S.C. § 119 to Japanese Patent Application No. 2023-145733 filed on Sep. 8, 2023, the entire contents of each of which are incorporated herein by reference.

### BACKGROUND

### Field

An exemplary embodiment of the present disclosure relates to an etching method and a plasma processing apparatus.

### Description of Related Art

An etching method described in Japanese Patent Application Laid-Open No. 2016-157793 is a technique of selectively etching a first region composed of silicon oxide with respect to a second region composed of silicon nitride.

### SUMMARY

In one exemplary embodiment of the present disclosure, there is provided an etching method executed in a plasma processing apparatus including a chamber, the etching method including: (a) preparing a substrate on a substrate support disposed in the chamber, the substrate including a first film and a second film, the first film containing silicon and nitrogen, and the second film containing silicon and oxygen; (b) supplying a processing gas including a metal-containing gas into the chamber; and (c) while the (b) is being executed, selectively etching the second film with respect to the first film, the (c) including (c1) forming a plasma by setting a power of a source RF signal having a first frequency to a first power, and supplying a first bias signal to the substrate support with a second power, the first bias signal having a frequency lower than the first frequency, and (c2) after the (c1), supplying the first bias signal to the substrate support with a third power higher than the second power.

### BRIEF DESCRIPTION OF DRAWINGS

FIG. 1 is a diagram illustrating a configuration example of a plasma processing system.

FIG. 2 is a diagram illustrating a configuration example of a capacitively coupled plasma processing apparatus.

FIG. 3 is a flowchart of an etching method according to one exemplary embodiment.

FIG. 4 is a diagram illustrating an example of a cross-sectional structure of a substrate W prepared in a step ST1.

FIG. 5 is a diagram illustrating an example of the cross-sectional structure of the substrate W after a part of a silicon oxide film is etched in a step ST2.

FIG. 6 is a timing chart illustrating an example of a source RF signal HF, a bias RF signal MF, and a bias RF signal LF in a step ST32.

FIG. 7 is a timing chart illustrating an example of the source RF signal HF, the bias RF signal MF, and the bias RF signal LF in the step ST32.

FIG. 8 is a timing chart illustrating an example of the source RF signal HF, the bias RF signal MF, and the bias RF signal LF in the step ST32.

FIG. 9 is a timing chart illustrating an example of the source RF signal HF, the bias RF signal MF, and the bias RF signal LF in the step ST32.

FIG. 10 is a timing chart illustrating an example of the source RF signal HF, the bias RF signal MF, and the bias RF signal LF in the step ST32.

FIG. 11 is a timing chart illustrating an example of the source RF signal HF, the bias RF signal MF, and the bias RF signal LF in the step ST32.

FIG. 12 is a timing chart illustrating an example of the source RF signal HF, the bias RF signal MF, and the bias RF signal LF in the step ST32.

FIG. 13 is a timing chart illustrating an example of the source RF signal HF, the bias RF signal MF, and the bias RF signal LF in the step ST32.

FIG. 14 is a diagram illustrating an example of the cross-sectional structure of the substrate W on which processing of a step ST3 is executed.

FIG. 15 is a diagram illustrating an example of the cross-sectional structure of the substrate W on which the processing of the step ST3 is executed.

FIG. 16 is a diagram illustrating an example of the cross-sectional structure of the substrate W.

FIG. 17 is a diagram illustrating an example of the cross-sectional structure of the substrate W on which the processing of the step ST3 is executed.

FIG. 18 is a diagram illustrating an example of the cross-sectional structure of the substrate W on which the processing of the step ST3 is executed.

### DETAILED DESCRIPTION

Hereinafter, each embodiment of the present disclosure will be described.

In one exemplary embodiment, an etching method executed in a plasma processing apparatus including a chamber is provided. The etching method includes (a) preparing a substrate on a substrate support disposed in the chamber, the substrate including a first film and a second film, the first film containing silicon and nitrogen, and the second film containing silicon and oxygen; (b) supplying a processing gas including a metal-containing gas into the chamber; and (c) while the (b) is being executed, selectively etching the second film with respect to the first film, the (c) including (c1) forming a plasma by setting a power of a source RF signal having a first frequency to a first power, and supplying a first bias signal to the substrate support with a second power, the first bias signal having a frequency that does not substantially contribute to the formation of the plasma, and (c2) after the (c1), supplying the first bias signal to the substrate support with a third power higher than the second power.

In one exemplary embodiment, in the (a), the substrate includes first regions and at least one second region between the first regions in plan view of the substrate, the first film is disposed in the first regions and includes a recess in the at least one second region, and the second film is disposed in the recess, and in the (c), the second film is selectively etched with respect to the first film, and at least a part of a side surface of the first film is exposed in the second region.

In one exemplary embodiment, in the (a), the second film is further disposed on the first film, and the substrate includes a mask including a first opening on the second film, and the mask is disposed on the second film in such a manner that the first opening overlaps the recess in plan view of the substrate, and in the (c), the second film is selectively etched with respect to the first film, a part of an upper surface of the first film is exposed in the first regions, and at least a part of the side surface of the first film is exposed in the second region.

In one exemplary embodiment, in the (a), the mask includes a second opening having a larger opening area than the first opening, the mask is disposed on the second film in such a manner that the second opening further overlaps the recess in plan view of the substrate, and the number of the recesses overlapping the first opening is smaller than the number of the recesses overlapping the second opening.

In one exemplary embodiment, the first film is disposed on the second film, and the first film includes an opening through which a part of the second film is exposed, and in the (c), in the opening, the part of the second film is selectively etched with respect to the first film to form a recess in the second film.

In one exemplary embodiment, the (c) further includes (c3) forming the plasma by setting the power of the source RF signal to a fifth power and supplying the first bias signal to the substrate support with the second power between the (c1) and the (c2), the fifth power being equal to or lower than the fourth power.

In one exemplary embodiment, the (c) further includes (c4) forming the plasma by setting the power of the source RF signal to a sixth power, and supplying the first bias signal to the substrate support with the second power between the (c1) and the (c3), the sixth power being lower than the first power and higher than the fourth power.

In one exemplary embodiment, the fourth power is zero power.

In one exemplary embodiment, the fourth power and the fifth power are each zero power.

In one exemplary embodiment, the fifth power is lower than the fourth power, and the fifth power is zero power.

In one exemplary embodiment, the second power is zero power.

In one exemplary embodiment, the first frequency is 60 MHz to 200 MHz.

In one exemplary embodiment, a frequency of the first bias signal is 100 kHz to 800 kHz.

In one exemplary embodiment, in the (c1), a second bias RF signal is supplied to the substrate support with a seventh power, and the second bias RF signal has a second frequency lower than the first frequency, and in the (c2), the second bias RF signal is supplied to the substrate support with an eighth power lower than the seventh power.

In one exemplary embodiment, the second frequency is 3 MHz to 40 MHz.

In one exemplary embodiment, the metal-containing gas is a gas including a tungsten-containing gas or a molybdenum-containing gas.

In one exemplary embodiment, the tungsten-containing gas includes tungsten fluoride.

In one exemplary embodiment, the processing gas includes a carbon-containing gas.

In one exemplary embodiment, the carbon-containing gas is a fluorocarbon gas.

In one exemplary embodiment, an etching method executed in a plasma processing apparatus including a chamber is provided. The etching method includes (a) preparing a substrate on a substrate support disposed in the chamber, the substrate including a first film and a second film, the first film containing at least one type selected from the group consisting of SiN, SiON, SiC, SiOC, and boron nitride, and the second film containing silicon and oxygen; (b) supplying a processing gas including a metal-containing gas into the chamber; and (c) while the (b) is being executed, selectively etching the second film with respect to the first film, the (c) including (c1) forming a plasma by setting a power of a source RF signal having a first frequency to a first power, and supplying a first bias signal to the substrate support with a second power, the first bias signal having a frequency that does not substantially contribute to the formation of the plasma, and (c2) after the (c1), supplying the first bias signal to the substrate support with a third power higher than the second power.

In one exemplary embodiment, a plasma processing apparatus including a chamber and a controller (i.e., controller circuitry) is provided. In the plasma processing apparatus, the controller circuitry is configured to execute (a) preparing a substrate on a substrate support disposed in the chamber, the substrate including a first film and a second film, the first film containing silicon and nitrogen, and the second film containing silicon and oxygen; (b) supplying a processing gas including a metal-containing gas into the chamber; and (c) while the (b) is being executed, selectively etching the second film with respect to the first film, the (c) including (c1) forming a plasma by setting a power of a source RF signal having a first frequency to a first power, and supplying a first bias signal to the substrate support with a second power, the first bias signal having a frequency that does not substantially contribute to the formation of the plasma or having a frequency that is lower than the first frequency, and (c2) after the (c1), supplying the first bias signal to the substrate support with a third power higher than the second power.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

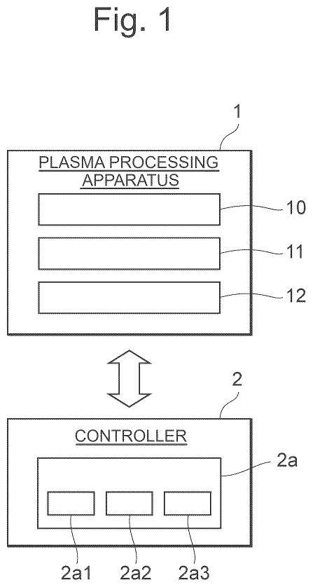

FIG. 1 is a diagram illustrating a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20, described later, and the gas exhaust port is connected to an exhaust system 40 described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency in the range of 100 kHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or all of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

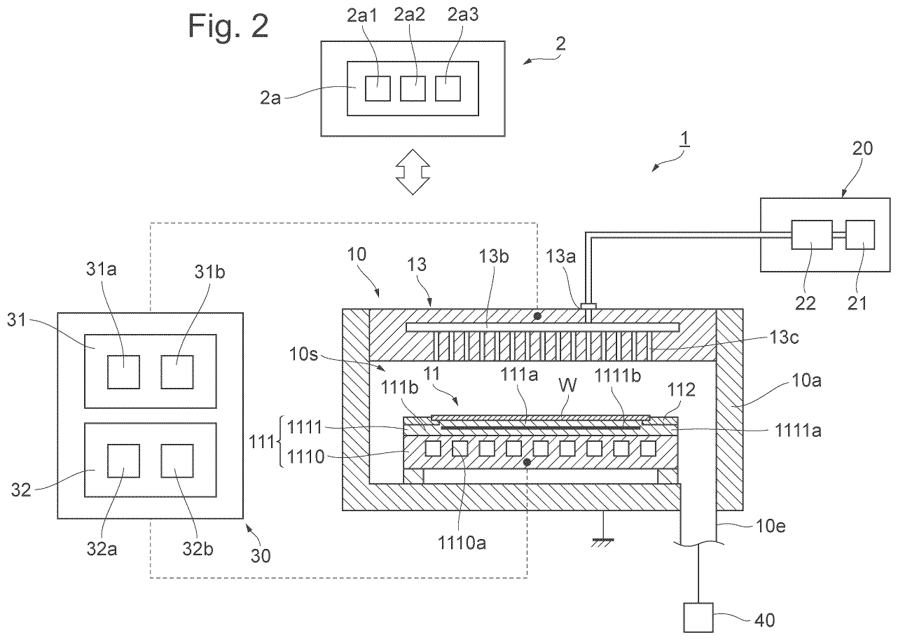

Hereinafter, a configuration example of a capacitively coupled plasma processing apparatus as an example of the plasma processing apparatus 1 will be described. FIG. 2 is a diagram illustrating the configuration example of the capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 constitutes at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. When a bias RF signal and/or a DC signal, which will be described later, are supplied to at least one RF/DC electrode, the RF/DC electrode is also referred to as a bias electrode. The conductive member of the base 1110 and at least one RF/DC electrode may function as the lower electrodes. Further, the electrostatic electrode 1111b may function as the lower electrode. Therefore, the substrate support 11 includes at least one lower electrode.

The ring assembly 112 includes one or multiple annular members. In an embodiment, one or the multiple annular members includes one or multiple edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or the multiple heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas into the plasma processing space 10s from the gas supply 20. The shower head 13 has at least one gas supply port 13a, at least one gas diffusion chamber 13b, and gas introduction ports 13c. The processing gas supplied to the gas supply port 13a passes through the gas diffusion chamber 13b and is introduced into the plasma processing space 10s from the gas introduction ports 13c. In addition, the shower head 13 includes at least one upper electrode. In addition to the shower head 13, the gas introducer may include one or multiple side gas injectors (SGI) attached to one or multiple opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. As a result, the plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma can be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHz. In an embodiment, the first RF generator 31a may be configured to generate source RF signals having different frequencies. The generated one or multiple source RF signals are supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has the frequency in the range of 100 kHz to 60 MHz. In an embodiment, the second RF generator 31b may be configured to generate bias RF signals having different frequencies. The generated one or multiple bias RF signals are supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes the first DC generator 32a and the second DC generator 32b. In an embodiment, the first DC generator 32a is connected to at least one lower electrode, and is configured to generate a first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure a voltage pulse generator. When the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or multiple voltage pulses of the positive polarity and one or multiple voltage pulses of the negative polarity in one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

### Example of Present Method

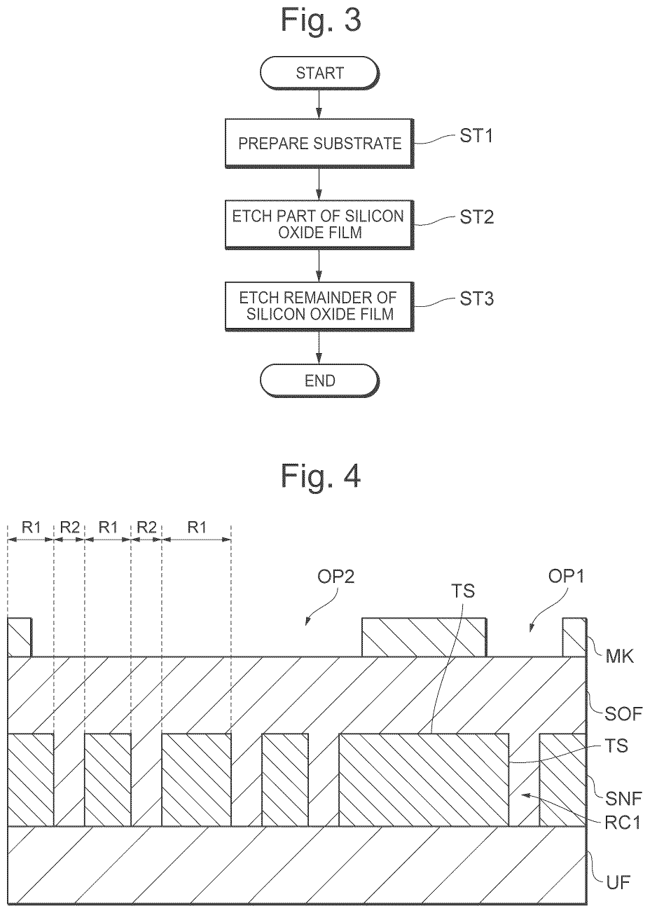

FIG. 3 is a flowchart illustrating an etching method according to one exemplary embodiment (hereinafter, also referred to as “the present method”). The present method includes a step of preparing a substrate (ST1), a step of etching a part of a silicon oxide film (ST2), and a step of etching the remainder of the silicon oxide film (ST3). In an embodiment, the processing in each step may be executed by the plasma processing apparatus 1 (see FIGS. 1 and 2). In the following examples, the controller 2 controls each unit of the capacitively coupled plasma processing apparatus 1 (see FIG. 2) to execute the present method.

### (Step ST1: Preparation of Substrate)

In the step ST1, the substrate is prepared. In the step ST1, the substrate W is disposed in the center region 111a of the substrate support 11 and is held in the substrate support 11 by the electrostatic chuck 1111. FIG. 4 is a diagram illustrating an example of a cross-sectional structure of the substrate W prepared in the step ST1. As illustrated in FIG. 4, the substrate W may be configured to include an underlying film UF, a silicon nitride film SNF, a silicon oxide film SOF, and a mask MK. The silicon nitride film SNF is an example of a film containing silicon and nitrogen. As the film containing silicon and nitrogen, in addition to the silicon nitride film, a SiON film can be used. In addition, as the substrate W, at least one type of film selected from the group consisting of a SiC film, a SiOC film, and a boron nitride film can be used instead of the film containing silicon and nitrogen or together with the film containing silicon and nitrogen. The silicon oxide film SOF is an example of a film containing silicon and oxygen. The substrate W may be used for manufacturing a semiconductor device.

In an embodiment, the substrate W has regions R1 and regions R2 in plan view of the substrate W. The region R1 is an example of a first region. The region R2 is an example of a second region. The region R1 and the region R2 may be regions adjacent to each other. The regions R1 illustrated as separated in the cross section illustrated in FIG. 4 may be regions continuous to other cross sections of the substrate W.

In an embodiment, the underlying film UF is a silicon wafer, an organic film, a dielectric film, a metal film, a semiconductor film, or the like formed on the silicon wafer. In an embodiment, the underlying film UF may include an etching stop film. As an example, the etching stop film may be a silicon nitride film.

In an embodiment, the underlying film UF may be configured by stacking films. When the underlying film UF is configured of the films, the etching stop film may be formed on an uppermost layer of the underlying film UF. That is, the etching stop film may be disposed to be in contact with the silicon oxide film SOF.

The silicon nitride film SNF may be disposed on the underlying film UF. In an embodiment, the silicon nitride film SNF may be disposed in the regions R1 in such a manner that the regions R2 include recesses RC/RC1 in plan view of the substrate W. The recess RC may be an opening penetrating the silicon nitride film SNF. The recess RC may be a space defined based on a side surface SS of the silicon nitride film SNF.

The silicon oxide film SOF is a film to be etched in the present method. In the present method, the silicon oxide film SOF is a film selectively etched with respect to the silicon nitride film SNF. In an embodiment, the silicon oxide film SOF may be disposed at least in the recess RC in plan view of the substrate W. That is, the silicon oxide film SOF may be disposed in the region R2 or the recess RC to be in contact with the side surface SS of the silicon nitride film SNF and the underlying film UF.

The silicon oxide film SOF may be disposed in both the region R1 and the region R2. That is, as illustrated in FIG. 4, the silicon oxide film SOF may be disposed on the silicon nitride film SNF in the region R1. In addition, the silicon oxide film SOF may be disposed in the recess RC in the region R2 and may also be disposed above the recess RC. That is, the silicon oxide film SOF may be disposed to cover the silicon nitride film SNF.

The mask MK includes an opening pattern for etching the silicon oxide film SOF. The opening pattern may include openings having different opening areas. In the example illustrated in FIG. 4, the mask MK has an opening OP1 and an opening OP2 (hereinafter, the opening OP1 and the opening OP2 are also collectively referred to as an “opening OP”). The opening OP1 is an example of a first opening. The opening OP2 is an example of a second opening. The opening OP may have any shape in plan view of the substrate W. The shape may be, for example, a circle, an ellipse, a rectangle, a line, or a shape in which one or more of these are combined. The mask MK may include side surfaces, and the side surfaces may define the openings OP. The openings OP may each have a linear shape and may be arranged at regular intervals to form a line & space pattern.

In an embodiment, the region R1 and the region R2 may have a line shape in a portion overlapping the opening OP. That is, the silicon nitride film SNF and the recess RC may be configured to have the line & space pattern in plan view of the substrate W. In an embodiment, the number of the recesses RC/RC1 overlapping the opening OP1 may be different from the number of the recesses RC/RC1 overlapping the opening OP2. As an example, as illustrated in FIG. 4, the number of the recesses RC/RC1 overlapping the opening OP1 may be one, and the number of the recesses RC/RC1 overlapping the opening OP2 may be plural. In addition, the opening OP1 and the opening OP2 may have different opening areas. That is, aspect ratios for etching the silicon oxide film SOF may be different in the opening OP1 and the opening OP2.

A material included in the mask MK may be appropriately selected depending on the type of the film to be etched. In an embodiment, the mask MK is formed of a material having an etching rate for the plasma formed in the step ST3 lower than an etching rate of the film to be etched.

In an embodiment, the mask MK is a carbon-containing mask, a silicon-containing mask, or a metal-containing mask. In an example, the carbon-containing mask is an amorphous carbon (ACL) film, a spin-on carbon (SOC) film, or a photoresist film. The ACL film may be doped with elements such as boron, arsenic, and tungsten. The metal-containing mask may be a metal-containing film containing at least one metal selected from the group consisting of tungsten (W), molybdenum (Mo), and titanium (Ti), or a carbide thereof.

### (Step ST2: Etching of Part of Silicon Oxide Film)

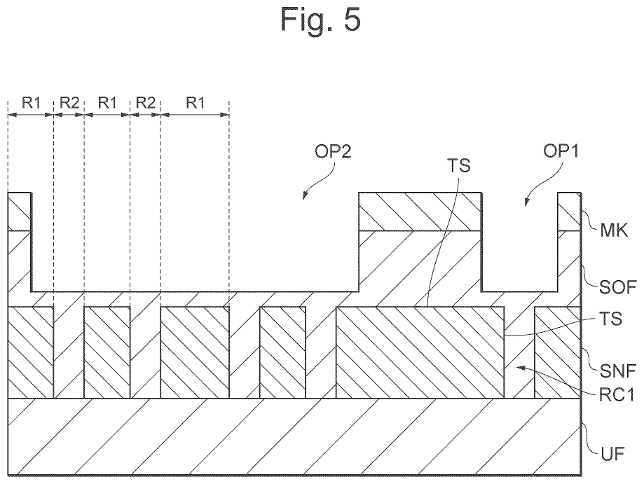

Next, in the step ST2, a part of the silicon oxide film SOF is etched. FIG. 5 is a diagram illustrating an example of the cross-sectional structure of the substrate W after a part of the silicon oxide film is etched in the step ST2. As illustrated in FIG. 5, in the silicon oxide film SOF, a part thereof is etched in the opening OP. In an embodiment, the silicon oxide film SOF may be etched to an extent that the silicon nitride film SNF is not exposed in the opening OP. As an example, a thickness of the silicon oxide film SOF present on the silicon nitride film SNF in the opening OP may be 10 nm or less or 5 nm or less. In addition, as an example, the thickness of the silicon oxide film SOF present on the silicon nitride film SNF in the opening OP may be 10% or less of the thickness of the silicon oxide film SOF present on the silicon nitride film SNF in a region other than the opening OP. In an embodiment, the silicon oxide film SOF may be etched until the silicon nitride film SNF is exposed in the region R1.

In the step ST2, the silicon oxide film SOF may be etched by the plasma formed from the processing gas. In an embodiment, the processing gas may include a fluorine-containing gas. The fluorine-containing gas may be a fluorocarbon gas and/or a hydrofluorocarbon gas. For example, the fluorocarbon gas may be at least one selected from the group consisting of CF₄ gas, C₂F₂ gas, C₂F₄ gas, C₃F₆ gas, C₃F₈ gas, C₄F₆ gas, C₄F₈ gas, and C₅F₈ gas.

In addition, in the step ST2, the plasma may be formed by supplying the source RF signal to the upper electrode or the lower electrode. The source RF signal supplied in the step ST2 may be a continuous wave. When the source RF signal is supplied to the upper electrode or the lower electrode in a state where the processing gas is supplied into the plasma processing chamber 10, the plasma is formed from the processing gas. Then, the active species in the plasma are drawn into the substrate W, and a part of the silicon oxide film SOF is etched by the active species in the opening OP. In step ST2, a bias signal may be supplied to the lower electrode.

### (Step ST3: Etching of Remainder of Silicon Oxide Film)

Next, in the step ST3, a remainder of the silicon oxide film SOF is etched. The step ST3 includes a step (ST31) of supplying the processing gas and a step (ST32) of supplying the source RF signal and the bias signal.

### (Step ST31: Supply of Processing Gas)

Next, in the step ST31, the processing gas is supplied into the plasma processing chamber 10. The execution of the step ST31 and the step ST32 may be started at the same time, or one may be started earlier than the other.

In the step ST31, the processing gas may include a gas different from the gas included in the processing gas for etching a part of the silicon oxide film SOF in the step ST2. In an embodiment, the processing gas in the step ST31 includes the metal-containing gas. The metal-containing gas may be a tungsten-containing gas. The tungsten-containing gas is a gas containing tungsten and halogen, and is, for example, a WFₓCl_{y} gas (x and y are each an integer of 0 or more and 6 or less, and a sum of x and y is 2 or more and 6 or less). Specifically, the tungsten-containing gas may be a gas containing tungsten and fluorine, such as a tungsten difluoride (WF₂) gas, a tungsten tetrafluoride (WF₄) gas, a tungsten pentafluoride (WF₅) gas, or a tungsten hexafluoride (WF₆) gas, or a gas containing tungsten and chlorine, such as a tungsten dichloride (WCl₂) gas, a tungsten tetrachloride (WCl₄) gas, a tungsten pentachloride (WCl₅) gas, or a tungsten hexachloride (WCl₆) gas. Among these, at least one of the WF₆ gas and the WCl₆ gas may be used. A flow rate of the tungsten-containing gas may be 5 vol % or less of a total flow rate of the processing gas. The processing gas may include at least one of a titanium-containing gas, a ruthenium-containing gas, and/or a molybdenum-containing gas, instead of or in addition to the tungsten-containing gas.

In the step ST31, the processing gas may further include a carbon-containing gas. The carbon-containing gas may be a fluorocarbon gas. For example, the fluorocarbon gas may be at least one selected from the group consisting of CF₄ gas, C₂F₂ gas, C₂F₄ gas, C₃F₆ gas, C₃F₈ gas, C₄F₆ gas, C₄F₈ gas, and C₅F₈ gas. In an embodiment, the carbon-containing gas is a linear gas having an unsaturated bond. As such a gas, for example, a hexafluoropropene (C₃F₆) gas, an octafluoro-1-butene, octafluoro-2-butene (C₄F₈) gas, a 1,3,3,3-tetrafluoropropene (C₃H₂F₄) gas, a trans-1,1,1,4,4,4-hexafluoro-2-butene (C₄H₂F₆) gas, a pentafluoroethyl trifluorovinyl ether (C₄F₈O) gas, a 1,2,2,2-tetrafluoroethan-1-one (CF₃COF) gas, a difluoroacetic fluoride (CHF₂COF) gas, and a carbonyl fluoride (COF₂) gas may be used. In an embodiment, the carbon-containing gas may contain a halogen element other than fluorine, or may contain fluorine and a halogen element other than fluorine. Such a gas may be CᵢHⱼFₖXₗ. Here, X is halogen other than fluorine. In addition, i and l may each be an integer of 1 or more, and j and k may each be an integer of 0 or more. The carbon-containing gas may include one or more gases of, for example, respective CHⱼClₗ, CFₖBrₗ, CFₖIₗ, and CᵢFₖClₗ. More specifically, the carbon-containing gas may be at least one selected from the group consisting of CHCl₃, CH₂Cl₂, and CF₂Br₂.

In the step ST31, the processing gas may further include an inert gas. The inert gas may be a noble gas such as an Ar gas, a He gas, or a Kr gas, and/or a nitrogen gas.

In the step ST31, the processing gas may further include a gas that captures (scavenges) an active species including fluorine. The gas that captures the active species containing fluorine may be an oxidizing gas or a reducing gas. As the oxidizing gas, carbon monoxide (CO) may be used. As the reducing gas, a hydrogen-containing gas such as hydrogen (H₂) may be used.

### (Step ST32: Supply of Source RF Signal and Bias Signal)

Next, in the step ST32, the source RF signal and the bias signal are supplied. The step ST32 is executed while the step ST31 is executed, and the plasma is formed from the processing gas in the plasma processing chamber 10.

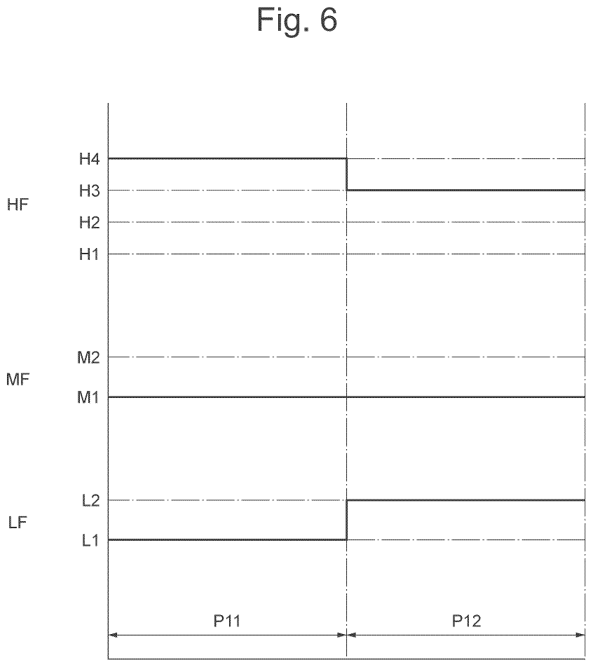

FIGS. 6 to 13 are timing charts illustrating examples of a source RF signal HF, a bias RF signal MF, and a bias RF signal LF. The source RF signal HF is an example of the source RF signal. The bias RF signal MF is an example of the second bias RF signal. The bias RF signal LF is an example of the first bias signal. The bias RF signal MF may have both functions of the source RF signal and the bias RF signal.

In FIGS. 6 to 13, a vertical axis indicates a relative value of power of each signal. The power may be an effective value of the power (hereinafter, also simply referred to as the “power”). In each drawing, the powers H1 to H4, the powers M1 and M2, and the powers L1 and L2 indicate a magnitude relationship of power in each signal. The absolute and/or relative power of the powers H1 to H4, the powers M1 and M2, and the powers L1 and L2 may be any set. In addition, in each drawing, a vertical axis does not indicate the relationship of power between the respective signals relatively.

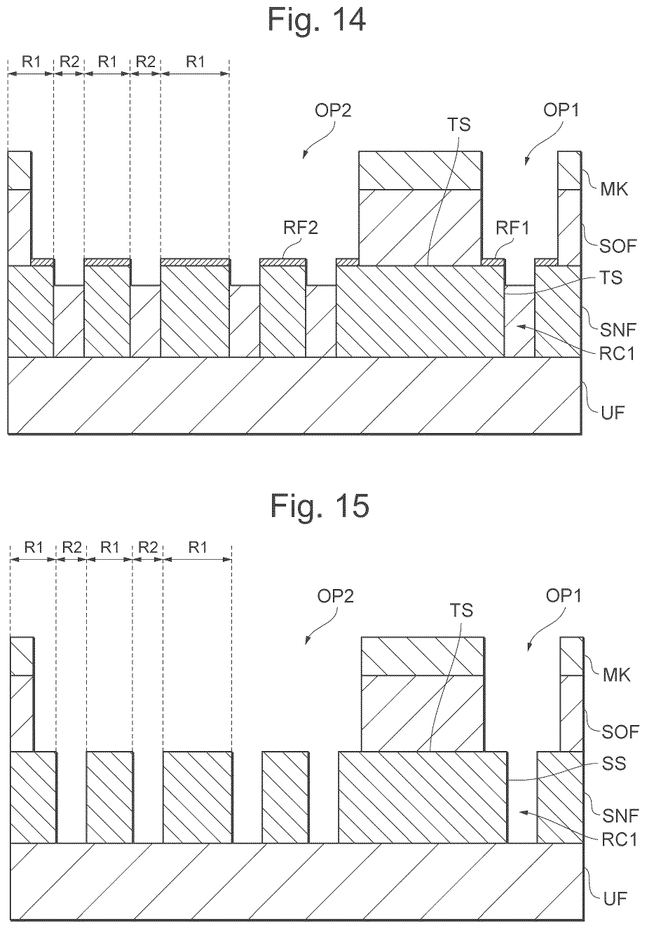

The power H1, the power M1, and the power L1 may be power that does not substantially contribute to the etching of the silicon oxide film SOF and/or the generation of a protective film PF (see FIG. 14). As an example, the power H1, the power M1, and the power L1 may be zero power (0 W, substantially 0 W (including, for example, standby power) or a wattage to an extent that it does not substantially contribute to the etching of the film to be etched).

In FIGS. 6 to 13, a horizontal axis indicates time. In addition, a total period illustrated in FIGS. 6 to 13 indicates one cycle of the step ST32. In each drawing, periods P11 and P12, periods P21 to P23, and periods P31 to P34 are illustrated to equally divide the cycle, respectively, but an absolute or relative time of each period may be any set.

In the examples illustrated in FIGS. 6 to 13, the frequency of the source RF signal HF may be 60 MHz to 200 MHz. As an example, the frequency of the source RF signal HF is 100 MHz. In addition, the frequency of the bias RF signal MF may be 3 MHz to 40 MHz. As an example, the frequency of the bias RF signal MF is 13 MHz. In addition, the frequency of the bias RF signal LF may be a frequency that does not substantially contribute to the formation of the plasma. The frequency may be, as an example, 100 kHz to 800 kHz. In addition, the frequency of the bias RF signal LF may be 400 kHz.

In an embodiment, each cycle illustrated in FIGS. 6 to 13 is repeatedly executed, and in the step ST32, the plasma is formed from the processing gas. As a result, the silicon oxide film SOF is selectively etched with respect to the silicon nitride film SNF.

FIGS. 14 and 15 are diagrams illustrating an example of the cross-sectional structure of the substrate W on which the processing of the step ST32 is executed. When the cycles illustrated in FIGS. 6 to 13 are repeatedly executed in the step ST3, as illustrated in FIG. 14, exposed portions of the silicon oxide film SOF in the opening OP1 and the opening OP2 are etched. As a result, as illustrated in FIG. 14, an upper surface TS of the silicon nitride film SNF is exposed. When the etching of the silicon oxide film SOF further proceeds in the step ST32, the protective film PF is formed on the upper surface TS of the silicon nitride film SNF, and the silicon oxide film SOF is etched in the recess RC. When the etching of the silicon oxide film SOF further proceeds in the step ST32, the underlying film UF is exposed in the recess RC, and the etching of the silicon oxide film SOF is ended. Hereinafter, details of the step ST32 in each of the examples of FIGS. 6 to 13 will be described.

In the example illustrated in FIG. 6, one cycle of the step ST32 includes the periods P11 and P12. First, in the period P11, the source RF signal HF is supplied to the upper electrode with the power H4. The upper electrode is an example of a counter electrode. In an embodiment, the power H4 may be 50 W to 2,000 W. As an example, the power H4 may be 200 W. In addition, in the period P11, the bias RF signal MF is supplied to the lower electrode with the power M1. In an embodiment, the power M1 may be 0 W to 20 W. As an example, the power M1 may be zero power. In addition, in the period P11, the bias RF signal LF is supplied to the lower electrode with the power L1. As an example, the power L1 may be zero power.

Next, in the period P12, the source RF signal HF is supplied to the upper electrode with the power H3. In an embodiment, the power H3 may be 20 W to 500 W. As an example, the power H3 may be 150 W. In addition, in the period P12, the bias RF signal MF is supplied to the lower electrode with the power M1. In addition, in the period P12, the bias RF signal LF is supplied to the lower electrode with the power L2. In an embodiment, the power L2 may be 10 W to 150 W. As an example, the power L2 may be 75 W.

In the example illustrated in FIG. 6, the periods P11 and P12 are repeatedly executed, and in the step ST32, the plasma is formed from the processing gas. In the present example, in the period P11, active species that contribute to the etching of the silicon oxide film SOF may be generated by the source RF signal HF. Then, in the period P12, the active species generated in the period P11 are drawn into the substrate W by the bias RF signal LF, and the silicon oxide film SOF is etched.

In addition, in the period P11, the active species for forming the protective film, which will be described later, are generated by the source RF signal HF, and the protective film PF may be formed on the silicon nitride film SNF.

In the example illustrated in FIG. 6, when the period P11 and the period P12 are repeatedly executed and the etching of the silicon oxide film SOF proceeds, the upper surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in the period P11. The active species may be the active species generated from the carbon-containing gas. In an embodiment, the protective film PF may be formed by forming an active site on the surface of the silicon nitride film SNF and adsorbing another active species to the active site. The active site and the active species may be active species generated in the period P11.

In the example illustrated in FIG. 6, when the etching of the silicon oxide film SOF further proceeds, the surface of the silicon nitride film SNF is protected by the protective film PF, and the silicon oxide film SOF is further etched in the recess RC (see FIG. 15). As described above, the silicon oxide film SOF is selectively etched with respect to the silicon nitride film SNF.

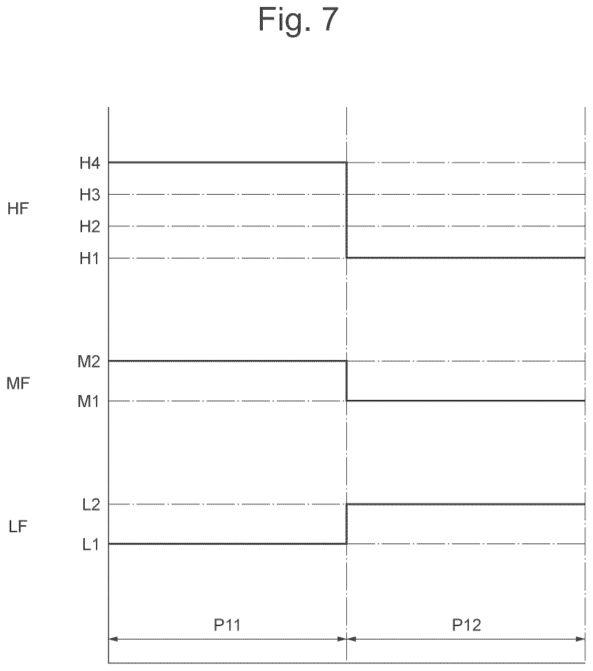

Next, an example illustrated in FIG. 7 will be described. In the example illustrated in FIG. 7, one cycle of the step ST32 includes the periods P11 and P12. First, in the period P11, the source RF signal HF is supplied to the upper electrode with the power H4. In an embodiment, the power H4 may be 50 W to 2,000 W. As an example, the power H4 may be 200 W. In addition, in the period P11, the bias RF signal MF is supplied to the lower electrode with the power M2. In an embodiment, the power M2 may be 10 W to 100 W. As an example, the power M2 may be 50 W. In addition, in the period P11, the bias RF signal LF is supplied to the lower electrode with the power L1. As an example, the power L1 may be zero power.

Next, in the period P12, the source RF signal HF is supplied to the upper electrode with the power H1. As an example, the power H1 may be 0 W. In addition, in the period P12, the bias RF signal MF is supplied to the lower electrode with the power M1. As an example, the power M1 may be zero power. In addition, in the period P12, the bias RF signal LF is supplied to the lower electrode with the power L2. In an embodiment, the power L2 may be 10 W to 150 W. As an example, the power L2 may be 75 W.

In the example illustrated in FIG. 7, the periods P11 and P12 are repeatedly executed, and in the step ST32, the plasma is formed from the processing gas. In the present example, in the period P11, active species that contribute to the etching of the silicon oxide film SOF may be generated by the source RF signal HF. Then, in the period P12, the active species generated in the period P11 are drawn into the substrate W by the bias RF signal LF, and the silicon oxide film SOF is etched.

In addition, in the period P11, the active species for forming the protective film, which will be described later, are generated by the source RF signal HF, and the protective film PF may be formed on the silicon nitride film SNF. In addition, an amount of the active species for forming the protective film PF and/or a composition of the protective film PF may be controlled by the bias RF signal MF. As an example, at least the surface of the protective film PF may be modified by the active species generated by the bias RF signal MF. The modification may include changing a ratio of elements contained in the protective film PF. In an embodiment, the modification includes changing a ratio of the number of fluorine atoms to the number of carbon atoms in the protective film PF. As an example, the modification may be carried out by lowering the ratio of the number of fluorine atoms to the number of carbon atoms in the protective film PF.

In the example illustrated in FIG. 7, when the period P11 and the period P12 are repeatedly executed and the etching of the silicon oxide film SOF proceeds, the upper surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated by the source RF signal HF in the period P11. The active species may be the active species generated from the carbon-containing gas. In an embodiment, the protective film PF may be formed by forming an active site on the surface of the silicon nitride film SNF and adsorbing another active species to the active site. The active site and the active species may be active species generated in the period P11.

In the example illustrated in FIG. 7, when the etching of the silicon oxide film SOF further proceeds, the surface of the silicon nitride film SNF is protected by the protective film PF, and the silicon oxide film SOF is further etched in the recess RC (see FIG. 15). As described above, the silicon oxide film SOF is selectively etched with respect to the silicon nitride film SNF.

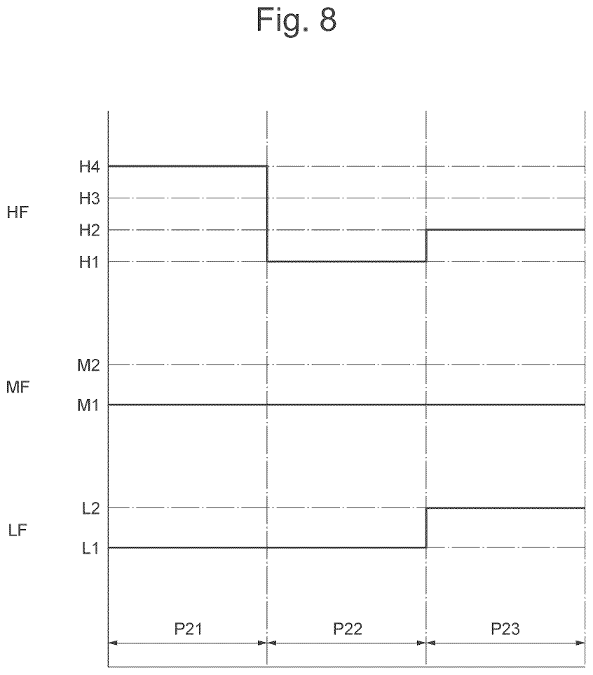

Next, an example illustrated in FIG. 8 will be described. In the example illustrated in FIG. 8, one cycle of the step ST32 includes the periods P21 to P23. First, in the period P21, the source RF signal HF is supplied to the upper electrode with the power H4. In an embodiment, the power H4 may be 50 W to 2,000 W. As an example, the power H4 may be 200 W. In addition, in the period P21, the bias RF signal MF is supplied to the lower electrode with the power M1. As an example, the power M1 may be zero power. In addition, in the period P21, the bias RF signal LF is supplied to the lower electrode with the power L1. As an example, the power L1 may be zero power.

Next, in the period P22, the source RF signal HF is supplied to the upper electrode with the power H1. As an example, the power H1 may be 0 W. In addition, in the period P22, the bias RF signal MF is supplied to the lower electrode with the power M1. In addition, in the period P22, the bias RF signal LF is supplied to the lower electrode with the power L1.

Next, in the period P23, the source RF signal HF is supplied to the upper electrode with the power H2. In an embodiment, the power H2 may be 20 W to 200 W. As an example, the power H2 may be 100 W. In addition, in the period P23, the bias RF signal MF is supplied to the lower electrode with the power M1. In addition, in the period P23, the bias RF signal LF is supplied to the lower electrode with the power L2. In an embodiment, the power L2 may be 10 W to 150 W. As an example, the power L2 may be 75 W.

In the example illustrated in FIG. 8, the periods P21 to P23 are repeatedly executed, and in the step ST32, the plasma is formed from the processing gas. In the present example, in the period P21, the active species that contribute to the etching of the silicon oxide film SOF may be generated by the source RF signal HF. Then, in the period P22, the powers of the source RF signal HF and the bias RF signal MF are lowered. Then, in the period P23, the active species generated in the period P21 are drawn into the substrate W by the bias RF signal LF, and the silicon oxide film SOF is etched. In addition, the plasma formed in the period P21 may be maintained by supplying the source RF signal HF to the upper electrode with the power H2 in the period P23.

In addition, in the period P21, the active species for forming the protective film, which will be described later, are generated by the source RF signal HF, and the protective film PF may be formed on the silicon nitride film SNF.

In the example illustrated in FIG. 8, when the periods P21 to P23 are repeatedly executed and the etching of the silicon oxide film SOF proceeds, the upper surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in the period P21. The active species may be the active species generated from the carbon-containing gas. In an embodiment, the protective film PF may be formed by forming an active site on the surface of the silicon nitride film SNF and adsorbing another active species to the active site. The active site and the active species may be the active species generated in the period P21.

In the example illustrated in FIG. 8, when the etching of the silicon oxide film SOF further proceeds, the surface of the silicon nitride film SNF is protected by the protective film PF, and the silicon oxide film SOF is further etched in the recess RC (see FIG. 15). As described above, the silicon oxide film SOF is selectively etched with respect to the silicon nitride film SNF.

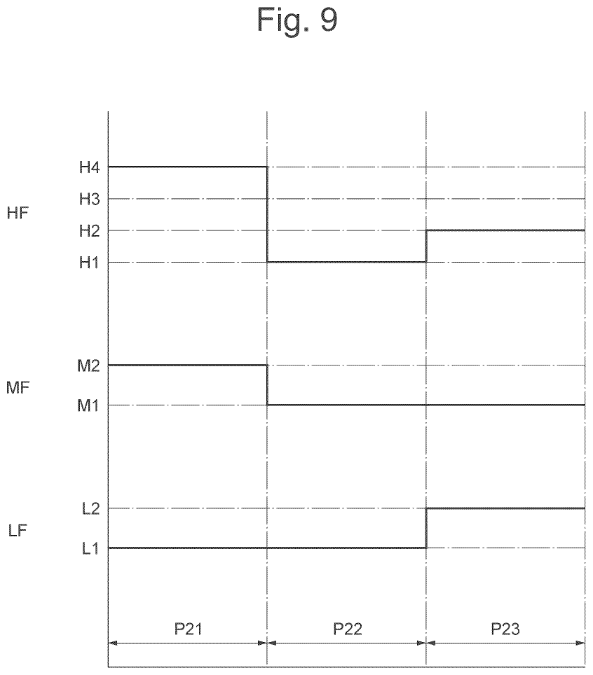

Next, an example illustrated in FIG. 9 will be described. In the example illustrated in FIG. 9, one cycle of the step ST32 includes the periods P21 to P23. First, in the period P21, the source RF signal HF is supplied to the upper electrode with the power H4. In an embodiment, the power H4 may be 50 W to 2,000 W. As an example, the power H4 may be 200 W. In addition, in the period P21, the bias RF signal MF is supplied to the lower electrode with the power M2. In an embodiment, the power M2 may be 10 W to 100 W. As an example, the power M2 may be 50 W. In addition, in the period P21, the bias RF signal LF is supplied to the lower electrode with the power L1. As an example, the power L1 may be zero power.

Next, in the period P22, the source RF signal HF is supplied to the upper electrode with the power H1. As an example, the power H1 may be 0 W. In addition, in the period P22, the bias RF signal MF is supplied to the lower electrode with the power M1. In addition, in the period P22, the bias RF signal LF is supplied to the lower electrode with the power L1.

Next, in the period P23, the source RF signal HF is supplied to the upper electrode with the power H2. In an embodiment, the power H2 may be 20 W to 200 W. As an example, the power H2 may be 100 W. In addition, in the period P23, the bias RF signal MF is supplied to the lower electrode with the power M1. In addition, in the period P23, the bias RF signal LF is supplied to the lower electrode with the power L2. In an embodiment, the power L2 may be 10 W to 150 W. As an example, the power L2 may be 75 W.

In the example illustrated in FIG. 9, the periods P21 to P23 are repeatedly executed, and in the step ST32, the plasma is formed from the processing gas. In the present example, in the period P21, the active species that contribute to the etching of the silicon oxide film SOF may be generated by the source RF signal HF. Then, in the period P22, the powers of the source RF signal HF and the bias RF signal MF are lowered. Then, in the period P23, the active species generated in the period P21 are drawn into the substrate W by the bias RF signal LF, and the silicon oxide film SOF is etched. In addition, the plasma formed in the period P21 may be maintained by supplying the source RF signal HF to the upper electrode with the power H2 in the period P23.

In addition, in the period P21, the active species for forming the protective film, which will be described later, are generated by the source RF signal HF, and the protective film PF may be formed on the silicon nitride film SNF. In addition, an amount of the active species for forming the protective film PF and/or a composition of the protective film PF may be controlled by the bias RF signal MF. As an example, at least the surface of the protective film PF may be modified by the active species generated by the bias RF signal MF.

In the example illustrated in FIG. 9, when the periods P21 to P23 are repeatedly executed and the etching of the silicon oxide film SOF proceeds, the upper surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in the period P21. The active species may be the active species generated from the carbon-containing gas. In an embodiment, the protective film PF may be formed by forming an active site on the surface of the silicon nitride film SNF and adsorbing another active species to the active site. The active site and the active species may be the active species generated in the period P21.

In the example illustrated in FIG. 9, when the etching of the silicon oxide film SOF further proceeds, the surface of the silicon nitride film SNF is protected by the protective film PF, and the silicon oxide film SOF is further etched in the recess RC (see FIG. 15). As described above, the silicon oxide film SOF is selectively etched with respect to the silicon nitride film SNF.

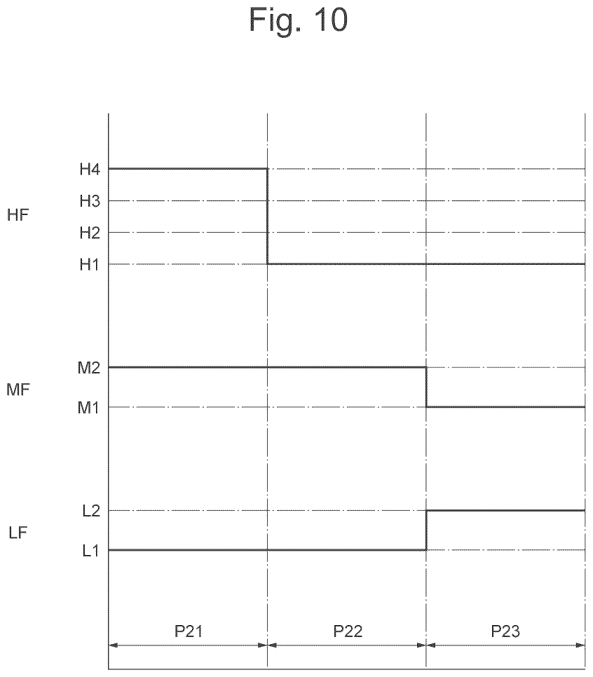

Next, an example illustrated in FIG. 10 will be described. In the example illustrated in FIG. 10, one cycle of the step ST32 includes the periods P21 to P23. First, in the period P21, the source RF signal HF is supplied to the upper electrode with the power H4. In an embodiment, the power H4 may be 50 W to 2,000 W. As an example, the power H4 may be 200 W. In addition, in the period P21, the bias RF signal MF is supplied to the lower electrode with the power M2. In an embodiment, the power M2 may be 10 W to 100 W. As an example, the power M2 may be 50 W. In addition, in the period P21, the bias RF signal LF is supplied to the lower electrode with the power L1. As an example, the power L1 may be zero power.

Next, in the period P22, the source RF signal HF is supplied to the upper electrode with the power H1. As an example, the power H1 may be 0 W. In addition, in the period P22, the bias RF signal MF is supplied to the lower electrode with the power M2. In addition, in the period P22, the bias RF signal LF is supplied to the lower electrode with the power L1.

Next, in the period P23, the source RF signal HF is supplied to the upper electrode with the power H1. As an example, the power H1 may be zero power. In addition, in the period P23, the bias RF signal MF is supplied to the lower electrode with the power M1. As an example, the power M1 may be zero power. In addition, in the period P23, the bias RF signal LF is supplied to the lower electrode with the power L2. In an embodiment, the power L2 may be 10 W to 150 W. As an example, the power L2 may be 75 W.

In the example illustrated in FIG. 10, the periods P21 to P23 are repeatedly executed, and in the step ST32, the plasma is formed from the processing gas. In the present example, in the period P21, the active species that contribute to the etching of the silicon oxide film SOF may be generated by the source RF signal HF. Then, in the period P22, the powers of the source RF signal HF and the bias RF signal MF are lowered. Then, in the period P23, the active species generated in the period P21 and the period P22 are drawn into the substrate W by the bias RF signal LF, and the silicon oxide film SOF is etched. In addition, the plasma formed in the period P21 may be maintained by supplying the bias RF signal MF to the lower electrode with the power M2 in the period P22.

In addition, in the period P21, the active species for forming the protective film, which will be described later, are generated by the source RF signal HF, and the protective film PF may be formed on the silicon nitride film SNF. In addition, an amount of the active species for forming the protective film PF and/or a composition of the protective film PF may be controlled by the bias RF signal MF. As an example, at least the surface of the protective film PF may be modified by the active species generated by the bias RF signal MF.

In the example illustrated in FIG. 10, when the periods P21 to P23 are repeatedly executed and the etching of the silicon oxide film SOF proceeds, the upper surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in the period P21. The active species may be the active species generated from the carbon-containing gas. In an embodiment, the protective film PF may be formed by forming an active site on the surface of the silicon nitride film SNF and adsorbing another active species to the active site. The active site and the active species may be active species generated in the period P21 and the period P23.

In the example illustrated in FIG. 10, when the etching of the silicon oxide film SOF further proceeds, the surface of the silicon nitride film SNF is protected by the protective film PF, and the silicon oxide film SOF is further etched in the recess RC (see FIG. 15). As described above, the silicon oxide film SOF is selectively etched with respect to the silicon nitride film SNF.

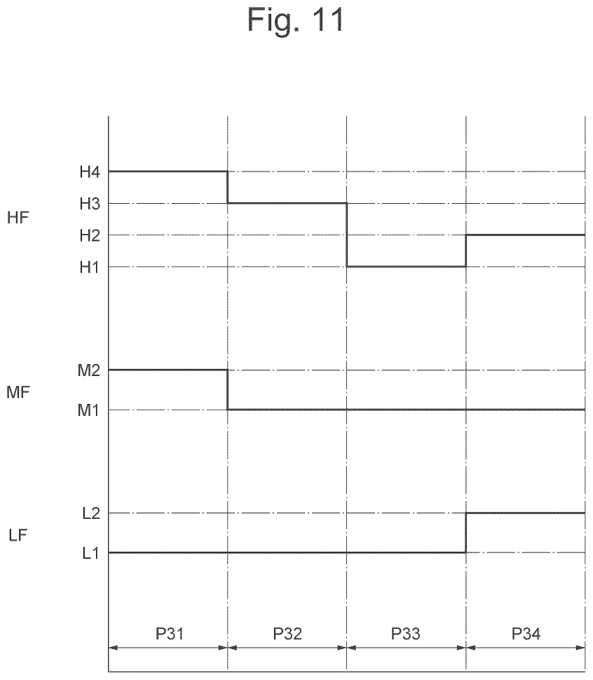

Next, an example illustrated in FIG. 11 will be described. In the example illustrated in FIG. 11, one cycle of the step ST32 includes the periods P31 to P34. First, in the period P31, the source RF signal HF is supplied to the upper electrode with the power H4. In an embodiment, the power H4 may be 50 W to 500 W. As an example, the power H4 may be 200 W. In addition, in the period P31, the bias RF signal MF is supplied to the lower electrode with the power M2. In an embodiment, the power M2 may be 10 W to 100 W. As an example, the power M2 may be 50 W. In addition, in the period P31, the bias RF signal LF is supplied to the lower electrode with the power L1. As an example, the power L1 may be zero power.

Next, in the period P32, the source RF signal HF is supplied to the upper electrode with the power H3. In an embodiment, the power H3 may be 20 W to 500 W. As an example, the power H3 may be 150 W. In addition, in the period P32, the bias RF signal MF is supplied to the lower electrode with the power M1. As an example, the power M1 may be zero power. In addition, in the period P32, the bias RF signal LF is supplied to the lower electrode with the power L1.

Next, in the period P33, the source RF signal HF is supplied to the upper electrode with the power H1. As an example, the power H1 may be zero power. In addition, in the period P33, the bias RF signal MF is supplied to the lower electrode with the power M1. In addition, in the period P33, the bias RF signal LF is supplied to the lower electrode with the power L1.

Next, in the period P34, the source RF signal HF is supplied to the upper electrode with the power H2. In an embodiment, the power H2 may be 20 W to 200 W. As an example, the power H2 may be 100 W. In addition, in the period P34, the bias RF signal MF is supplied to the lower electrode with the power M1. As an example, the power M1 may be zero power. In addition, in the period P34, the bias RF signal LF is supplied to the lower electrode with the power L2. In an embodiment, the power L2 may be 10 W to 150 W. As an example, the power L2 may be 75 W.

In the example illustrated in FIG. 11, the periods P31 to P34 are repeatedly executed, and in the step ST32, the plasma is formed from the processing gas. In the present example, in the period P31 and the period P32, the active species that contribute to the etching of the silicon oxide film SOF may be generated by the source RF signal HF. Then, in the period P33, the powers of the source RF signal HF and the bias RF signal MF are lowered. Then, in the period P34, the active species generated in the period P31 and the period P32 are drawn into the substrate W by the bias RF signal LF, and the silicon oxide film SOF is etched. In addition, the plasma formed in the period P31 and the period P32 may be maintained by supplying the source RF signal HF to the upper electrode with the power H2 in the period P34.

In addition, in the period P31 and the period P32, the active species for forming the protective film, which will be described later, are generated by the source RF signal HF, and the protective film PF may be formed on the silicon nitride film SNF. In addition, an amount of the active species for forming the protective film PF and/or a composition of the protective film PF may be controlled by the bias RF signal MF. As an example, at least the surface of the protective film PF may be modified by the active species generated by the bias RF signal MF.

In the example illustrated in FIG. 11, when the periods P31 to P34 are repeatedly executed and the etching of the silicon oxide film SOF proceeds, the upper surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in the period P31. The active species may be the active species generated from the carbon-containing gas. In an embodiment, the protective film PF may be formed by forming an active site on the surface of the silicon nitride film SNF and adsorbing another active species to the active site. The active site and the active species may be the active species generated in the period P31 and the period P32.

In the example illustrated in FIG. 11, when the etching of the silicon oxide film SOF further proceeds, the surface of the silicon nitride film SNF is protected by the protective film PF, and the silicon oxide film SOF is further etched in the recess RC (see FIG. 15). As described above, the silicon oxide film SOF is selectively etched with respect to the silicon nitride film SNF.

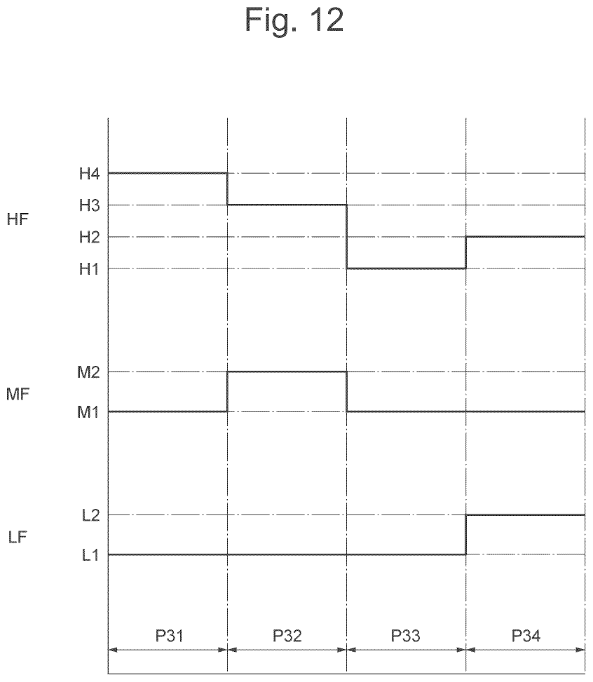

Next, an example illustrated in FIG. 12 will be described. In the example illustrated in FIG. 12, one cycle of the step ST32 includes the periods P31 to P34. First, in the period P31, the source RF signal HF is supplied to the upper electrode with the power H4. In an embodiment, the power H4 may be 50 W to 2,000 W. As an example, the power H4 may be 200 W. In addition, in the period P31, the bias RF signal MF is supplied to the lower electrode with the power M1. As an example, the power M1 may be zero power. In addition, in the period P31, the bias RF signal LF is supplied to the lower electrode with the power L1. As an example, the power L1 may be zero power.

Next, in the period P32, the source RF signal HF is supplied to the upper electrode with the power H3. In an embodiment, the power H3 may be 20 W to 500 W. As an example, the power H3 may be 150 W. In addition, in the period P32, the bias RF signal MF is supplied to the lower electrode with the power M2. In an embodiment, the power M2 may be 10 W to 100 W. As an example, the power M2 may be 50 W. In addition, in the period P32, the bias RF signal LF is supplied to the lower electrode with the power L1.

Next, in the period P33, the source RF signal HF is supplied to the upper electrode with the power H1. As an example, the power H1 may be zero power. In addition, in the period P33, the bias RF signal MF is supplied to the lower electrode with the power M1. In addition, in the period P33, the bias RF signal LF is supplied to the lower electrode with the power L1.

Next, in the period P34, the source RF signal HF is supplied to the upper electrode with the power H2. In an embodiment, the power H2 may be 20 W to 200 W. As an example, the power H2 may be 100 W. In addition, in the period P34, the bias RF signal MF is supplied to the lower electrode with the power M1. As an example, the power M1 may be zero power. In addition, in the period P34, the bias RF signal LF is supplied to the lower electrode with the power L2. In an embodiment, the power L2 may be 10 W to 150 W. As an example, the power L2 may be 75 W.

In the example illustrated in FIG. 12, the periods P31 to P34 are repeatedly executed, and in the step ST32, the plasma is formed from the processing gas. In the present example, in the period P31 and the period P32, the active species that contribute to the etching of the silicon oxide film SOF may be generated by the source RF signal HF. Then, in the period P33, the powers of the source RF signal HF and the bias RF signal MF are lowered. Then, in the period P34, the active species generated in the period P31 and the period P32 are drawn into the substrate W by the bias RF signal LF, and the silicon oxide film SOF is etched. In addition, the plasma formed in the period P31 and the period P32 may be maintained by supplying the source RF signal HF to the upper electrode with the power H2 in the period P34.

In addition, in the period P31 and the period P32, the active species for forming the protective film, which will be described later, are generated by the source RF signal HF, and the protective film PF may be formed on the silicon nitride film SNF. In addition, an amount of the active species for forming the protective film PF and/or a composition of the protective film PF may be controlled by the bias RF signal MF. As an example, at least the surface of the protective film PF may be modified by the active species generated by the bias RF signal MF.

In the example illustrated in FIG. 12, when the periods P31 to P34 are repeatedly executed and the etching of the silicon oxide film SOF proceeds, the upper surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in the period P31. The active species may be the active species generated from the carbon-containing gas. In an embodiment, the protective film PF may be formed by forming an active site on the surface of the silicon nitride film SNF and adsorbing another active species to the active site. The active site and the active species may be the active species generated in the period P31 and the period P32.

In the example illustrated in FIG. 12, when the etching of the silicon oxide film SOF further proceeds, the surface of the silicon nitride film SNF is protected by the protective film PF, and the silicon oxide film SOF is further etched in the recess RC (see FIG. 15). As described above, the silicon oxide film SOF is selectively etched with respect to the silicon nitride film SNF.

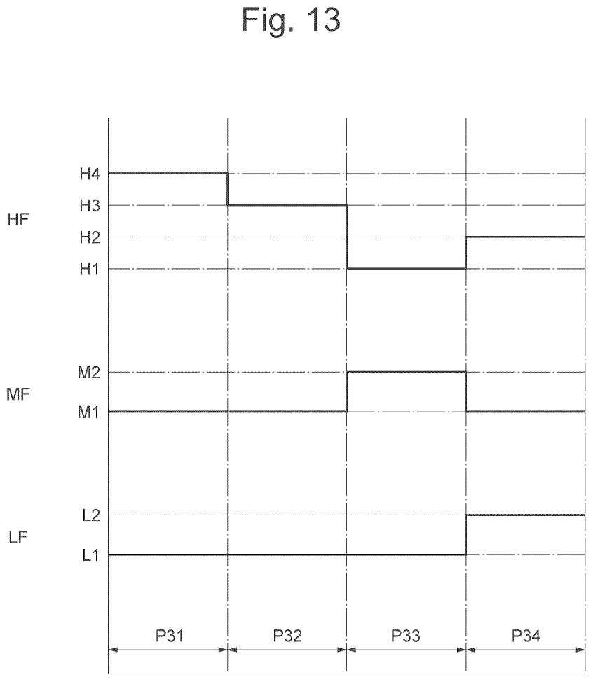

Next, an example illustrated in FIG. 13 will be described. In the example illustrated in FIG. 13, one cycle of the step ST32 includes the periods P31 to P34. First, in the period P31, the source RF signal HF is supplied to the upper electrode with the power H4. In an embodiment, the power H4 may be 50 W to 2,000 W. As an example, the power H4 may be 200 W. In addition, in the period P31, the bias RF signal MF is supplied to the lower electrode with the power M1. As an example, the power M1 may be zero power. In addition, in the period P31, the bias RF signal LF is supplied to the lower electrode with the power L1. As an example, the power L1 may be zero power.

Next, in the period P32, the source RF signal HF is supplied to the upper electrode with the power H3. In an embodiment, the power H3 may be 20 W to 500 W. As an example, the power H3 may be 150 W. In addition, in the period P32, the bias RF signal MF is supplied to the lower electrode with the power M1. In addition, in the period P32, the bias RF signal LF is supplied to the lower electrode with the power L1.

Next, in the period P33, the source RF signal HF is supplied to the upper electrode with the power H1. As an example, the power H1 may be zero power. In addition, in the period P33, the bias RF signal MF is supplied to the lower electrode with the power M2. In an embodiment, the power M2 may be 10 W to 100 W. As an example, the power M2 may be 50 W. In addition, in the period P33, the bias RF signal LF is supplied to the lower electrode with the power L1.

Next, in the period P34, the source RF signal HF is supplied to the upper electrode with the power H2. In an embodiment, the power H2 may be 20 W to 200 W. As an example, the power H2 may be 100 W. In addition, in the period P34, the bias RF signal MF is supplied to the lower electrode with the power M1. As an example, the power M1 may be zero power. In addition, in the period P34, the bias RF signal LF is supplied to the lower electrode with the power L2. In an embodiment, the power L2 may be 10 W to 150 W. As an example, the power L2 may be 75 W.

In the example illustrated in FIG. 13, the periods P31 to P34 are repeatedly executed, and in the step ST32, the plasma is formed from the processing gas. In the present example, in the period P31 and the period P32, the active species that contribute to the etching of the silicon oxide film SOF may be generated by the source RF signal HF. Then, in the period P33, the powers of the source RF signal HF and the bias RF signal MF are lowered. Then, in the period P34, the active species generated in the period P31 and the period P32 are drawn into the substrate W by the bias RF signal LF, and the silicon oxide film SOF is etched. In addition, the plasma formed in the period P31, the period P32, and/or the period P33 may be maintained by supplying the source RF signal HF to the upper electrode with the power H2 in the period P34.

In addition, in the period P31, the period P32, and/or the period P33, the active species for forming the protective film, which will be described later, are generated by the source RF signal HF, and the protective film PF may be formed on the silicon nitride film SNF. In addition, an amount of the active species for forming the protective film PF and/or a composition of the protective film PF may be controlled by the bias RF signal MF. As an example, at least the surface of the protective film PF may be modified by the active species generated by the bias RF signal MF.

In the example illustrated in FIG. 13, when the periods P31 to P34 are repeatedly executed and the etching of the silicon oxide film SOF proceeds, the upper surface TS of the silicon nitride film SNF is exposed (see FIG. 14). When the surface of the silicon nitride film SNF is exposed, the protective film PF may be generated on the surface of the silicon nitride film SNF. The protective film PF may be formed by the active species generated in the period P31. The active species may be the active species generated from the carbon-containing gas. In an embodiment, the protective film PF may be formed by forming an active site on the surface of the silicon nitride film SNF and adsorbing another active species to the active site. The active site and the active species may be the active species generated in the periods P31 to P33.

In the example illustrated in FIG. 13, when the etching of the silicon oxide film SOF further proceeds, the surface of the silicon nitride film SNF is protected by the protective film PF, and the silicon oxide film SOF is further etched in the recess RC (see FIG. 15). As described above, the silicon oxide film SOF is selectively etched with respect to the silicon nitride film SNF.

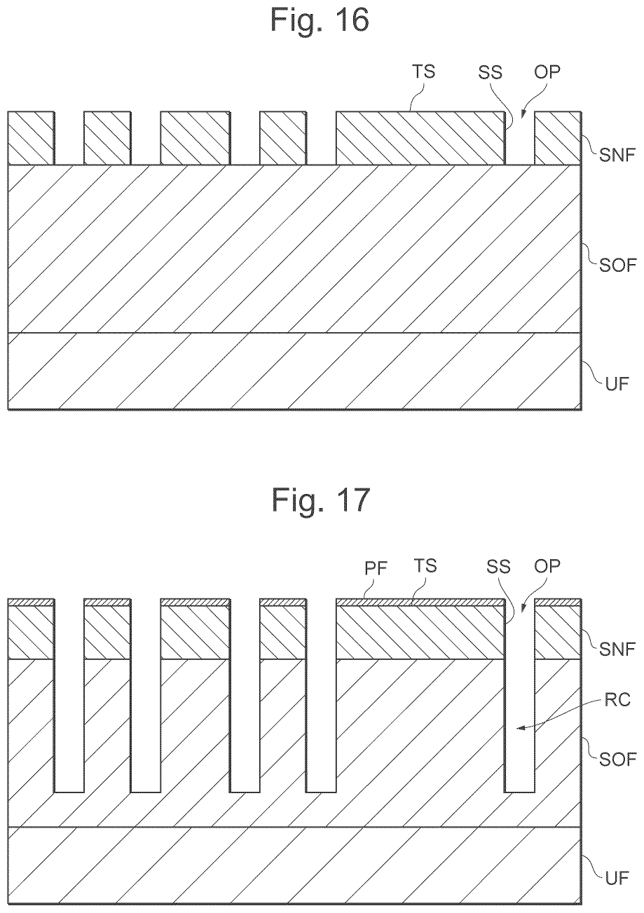

FIGS. 16 to 18 are diagrams illustrating an example of the cross-sectional structure of the substrate W. In FIGS. 16 to 18, the configurations denoted by the same reference numerals as those in FIGS. 14 and 15 have the same functions and/or features as the configurations in FIGS. 14 and 15. In the example illustrated in FIG. 16, the silicon nitride film SNF is disposed on the silicon oxide film SOF in the substrate W. The silicon nitride film SNF includes an opening pattern for etching the silicon oxide film SOF. The opening pattern may include openings OP.

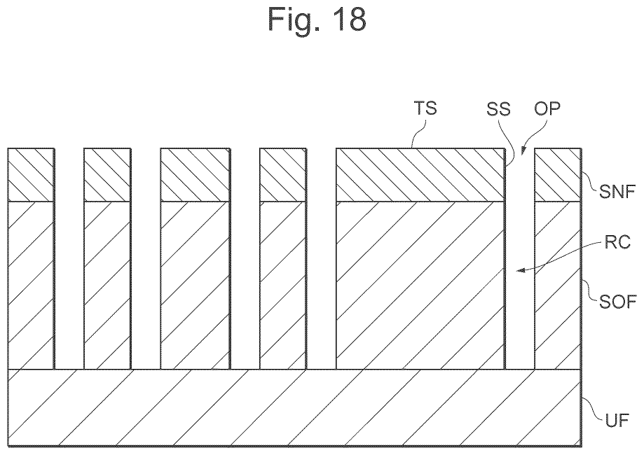

In the examples illustrated in FIGS. 16 to 18, the silicon oxide film SOF is etched using the silicon nitride film SNF as a mask. That is, the silicon oxide film SOF is selectively etched with respect to the silicon nitride film SNF. The silicon oxide film SOF may be etched by the same method as the present method described with reference to FIG. 3. That is, in the example illustrated in FIG. 16, when the etching processing according to the present method is executed, as illustrated in FIG. 17, while the protective film PF is formed on the upper surface TS of the nitride film SNF, the silicon oxide film SOF is etched, and the recess RC is formed on the silicon oxide film SOF. As illustrated in FIG. 18, the silicon oxide film SOF may be etched until the underlying film UF is exposed.

In one exemplary embodiment of the present disclosure, after supplying the source RF signal HF to the upper electrode with the relatively high power (as an example, the power H4), the source RF signal HF is switched to the relatively low power (as an example, the power H1 or H2), while after supplying the bias RF signal LF to the lower electrode with the relatively low power (as an example, the power L1), the bias RF signal LF is switched to the relatively high power (as an example, the power L2). As a result, the active species in the plasma can be drawn into the substrate W in a state where the electron density in the plasma is relatively low. Therefore, it is possible to suppress the spread of the critical dimension (CD) of the recess RC. In addition, a loading effect can be suppressed between the openings OP having different opening areas (as an example, the openings OP1 and OP2). As a result, it is possible to suppress a difference in thickness of the protective film PF between the openings OP having different opening areas.

In one exemplary embodiment of the present disclosure, after supplying the source RF signal HF to the upper electrode with the relatively high power (as an example, the power H4), in a period during which the source RF signal HF is set to a power (as an example, the power H1) further relatively lower than the low power, the source RF signal HF may be switched to relatively low power (as an example, the power H2). As a result, when the bias RF signal LF is switched to and maintained at the relatively high power (as an example, the power L2), the electron density in the plasma can be stabilized.

In one exemplary embodiment of the present disclosure, before switching the bias RF signal LF to the relatively high power (as an example, the power L2), the power of the source RF signal HF is gradually decreased (as an example, the power H4 and H3). As a result, when the bias RF signal LF is switched to and maintained at the relatively high power (as an example, the power L2) (as an example, the period P34), the electron density in the plasma can be stabilized.

In one exemplary embodiment of the present disclosure, before switching the bias RF signal LF to the relatively high power (as an example, the power L2), the bias RF signal MF is supplied to the lower electrode with the relatively high power (as an example, the power M2) at an appropriate timing (as an example, the period P21, P22, P31, P32, or P33). As a result, the plasma formed by the source RF signal HF can be stably maintained and/or the electron density in the plasma can be controlled.

The present disclosure provides an etching technique capable of improving selectivity.

The present disclosure may include, for example, the following configurations.

### Aspect 1

An etching method executed in a plasma processing apparatus including a chamber, the etching method including:
(a) preparing a substrate on a substrate support disposed in the chamber, the substrate including a first film and a second film, the first film containing silicon and nitrogen, and the second film containing silicon and oxygen;
(b) supplying a processing gas including a metal-containing gas into the chamber; and
(c) while the (b) is being executed, selectively etching the second film with respect to the first film, the (c) including
   (c1) forming a plasma by setting a power of a source RF signal having a first frequency to a first power, and supplying a first bias signal to the substrate support with a second power, the first bias signal having a frequency that does not substantially contribute to the formation of the plasma or having a frequency lower than the first frequency, and
   (c2) after the (c1), supplying the first bias signal to the substrate support with a third power higher than the second power.

An example of each power is as follows.
First power: power H4
Second power: power L1
Third power: power L2

### Aspect 2

The etching method according to Aspect 1, in which the (c2) further includes setting the power of the source RF signal to a fourth power lower than the first power.

An example of the fourth power is the power H1, H2, and/or H3.

### Aspect 3

The etching method according to Aspect 1,
in which in the (a), the substrate includes first regions and at least one second region between the first regions in a plan view of the substrate, the first film is disposed in the first regions and includes at least one recess in the at least one second region, and the second film is disposed in the at least one recess, and
in the (c), the second film is selectively etched with respect to the first film, and at least a part of a side surface of the first film is exposed in the at least one second region.

### Aspect 4

The etching method according to Aspect 2,
in which in the (a), the second film is further disposed on the first film, and the substrate includes a mask including a first opening on the second film, and the mask is disposed on the second film in such a manner that the first opening overlaps the at least one recess in the plan view of the substrate, and
in the (c), the second film is selectively etched with respect to the first film, a part of an upper surface of the first film is exposed in the first regions, and at least a part of the side surface of the first film is exposed in the second region.

### Aspect 5

The etching method according to Aspect 4, in which in the (a), the mask includes a second opening having a larger opening area than the first opening, the mask is disposed on the second film in such a manner that the second opening further overlaps the at least one recess in the plan view of the substrate, the at least one recess of the first film includes a plurality of recesses, and a number of the plurality of recesses overlapping the first opening is smaller than a number of the plurality of recesses overlapping the second opening.

### Aspect 6

The etching method according to Aspect 1,
in which the first film is disposed on the second film, and the first film includes an opening through which a part of the second film is exposed, and
in the (c), in the opening, the part of the second film is selectively etched with respect to the first film to form a recess in the second film.

### Aspect 7

The etching method according to Aspect 2, in which the (c) further includes (c3) forming the plasma by setting the power of the source RF signal to a fifth power and supplying the first bias signal to the substrate support with the second power between the (c1) and the (c2), the fifth power being equal to or lower than the fourth power.

An example of the fifth power is the power H1, H2, and/or H3.

### Aspect 8

The etching method according to Aspect 7, in which the (c) further includes (c4) forming the plasma by setting the power of the source RF signal to a sixth power, and supplying the first bias signal to the substrate support with the second power between the (c1) and the (c3), the sixth power being lower than the first power and higher than the fourth power.

An example of the sixth power is the power H2 and/or H3.

### Aspect 9

The etching method according to Aspect 2, in which the fourth power is zero power.

### Aspect 10

The etching method according to Aspect 7, in which the fourth power and the fifth power are each zero power.

### Aspect 11

The etching method according to Aspect 7, in which the fifth power is lower than the fourth power, and the fifth power is zero power.

### Aspect 12

The etching method according to any one of Addenda 1 to 11, in which the second power is zero power.

### Aspect 13

The etching method according to any one of Addenda 1 to 12, in which the first frequency is 60 MHz to 200 MHz.

### Aspect 14

The etching method according to any one of Addenda 1 to 13, in which a frequency of the first bias signal is 100 kHz to 800 kHz.

### Aspect 15

The etching method according to any one of Addenda 1 to 14,
in which in the (c1), a second bias RF signal is supplied to the substrate support with a seventh power, and the second bias RF signal has a second frequency lower than the first frequency, and
in the (c2), the second bias RF signal is supplied to the substrate support with an eighth power lower than the seventh power.

An example of each power is as follows.
Seventh power: power M2
Eighth power: power M1

### Aspect 16

The etching method according to Aspect 15, in which the second frequency is 3 MHz to 40 MHz.

### Aspect 17

The etching method according to any one of Addenda 1 to 16, in which the metal-containing gas is a gas including a tungsten-containing gas or a molybdenum-containing gas.

### Aspect 18

The etching method according to Aspect 17, in which the tungsten-containing gas includes tungsten fluoride.

### Aspect 19

The etching method according to any one of Addenda 1 to 16, in which the processing gas includes a carbon-containing gas.

### Aspect 20

The etching method according to Aspect 19, in which the carbon-containing gas is a fluorocarbon gas.

### Aspect 21

An etching method executed in a plasma processing apparatus including a chamber, the etching method including:
(a) controlling an electrostatic chuck to hold a substrate on a substrate support disposed in the chamber, the substrate including a first film and a second film, the first film containing at least one type selected from the group consisting of SiN, SiON, SiC, SiOC, and boron nitride, and the second film containing silicon and oxygen;
(b) supplying a processing gas including a metal-containing gas into the chamber; and
(c) while the (b) is being executed, selectively etching the second film with respect to the first film, the (c) including
   (c1) forming a plasma by setting a power of a source RF signal having a first frequency to a first power, and supplying a first bias signal to the substrate support with a second power, the first bias signal having a frequency that does not substantially contribute to the formation of the plasma, and
   (c2) after the (c1), supplying the first bias signal to the substrate support with a third power higher than the second power.

### Aspect 22

A plasma processing apparatus including:
a chamber;
a substrate support disposed in the chamber and including an electrostatic chuck; and
controller circuitry,
in which the controller circuitry is configured to execute:
(a) controlling the electrostatic chuck to hold a substrate on the substrate support, the substrate including a first film and a second film, the first film containing silicon and nitrogen, and the second film containing silicon and oxygen;
(b) supplying a processing gas including a metal-containing gas into the chamber; and
(c) while the (b) is being executed, selectively etching the second film with respect to the first film, the (c) including
   (c1) forming a plasma by setting a power of a source RF signal having a first frequency to a first power, and supplying a first bias signal to the substrate support with a second power, the first bias signal having a frequency that does not substantially contribute to the formation of the plasma, and
   (c2) after the (c1), supplying the first bias signal to the substrate support with a third power higher than the second power.

The above-described exemplary embodiments may be modified in various ways without departing from the scope and the spirit of the present disclosure. For example, some configuration elements in one embodiment can be added to another embodiment within the range of the ordinary creativity of those skilled in the art. In addition, some configuration elements in one embodiment can be replaced with corresponding configuration elements in another embodiment.

What is claimed is:

1. An etching method executed in a plasma processing apparatus including a chamber, the etching method comprising:
(a) preparing a substrate on a substrate support disposed in the chamber, the substrate including a first film and a second film, the first film containing silicon and nitrogen, and the second film containing silicon and oxygen;
(b) supplying a processing gas including a metal-containing gas into the chamber; and
(c) while the (b) is being executed, selectively etching the second film with respect to the first film, the (c) including:
(c1) forming a plasma by setting a power of a source RF signal having a first frequency to a first power, and supplying a first bias signal to the substrate support with a second power, the first bias signal having a frequency lower than the first frequency, and
(c2) after the (c1), supplying the first bias signal to the substrate support with a third power higher than the second power.

2. The etching method according to claim 1, wherein the (c2) further includes setting the power of the source RF signal to a fourth power lower than the first power.

3. The etching method according to claim 1, wherein in the (a), the substrate includes first regions and at least one second region between the first regions in a plan view of the substrate, the first film is disposed in the first regions and includes at least one recess in the at least one second region, and the second film is disposed in the at least one recess, and
in the (c), the second film is selectively etched with respect to the first film, and at least a part of a side surface of the first film is exposed in the at least one second region.

4. The etching method according to claim 3, wherein in the (a), the second film is further disposed on the first film, and the substrate includes a mask including a first opening on the second film, and the mask is disposed on the second film in such a manner that the first opening overlaps the at least one recess in the plan view of the substrate, and
in the (c), the second film is selectively etched with respect to the first film, a part of an upper surface of the first film is exposed in the first regions, and at least a part of the side surface of the first film is exposed in the at least one second region.

5. The etching method according to claim 4, wherein in the (a), the mask includes a second opening having a larger opening area than the first opening, the mask is disposed on the second film in such a manner that the second opening further overlaps the at least one recess in the plan view of the substrate,
the at least one recess of the first film includes a plurality of recesses,
and a number of the plurality of recesses overlapping the first opening is smaller than a number of the plurality of recesses overlapping the second opening.

6. The etching method according to claim 1, wherein the first film is disposed on the second film, and the first film includes an opening through which a part of the second film is exposed, and
in the (c), in the opening, the part of the second film is selectively etched with respect to the first film to form a recess in the second film.

7. The etching method according to claim 2, wherein the (c) further includes (c3) forming the plasma by setting the power of the source RF signal to a fifth power and supplying the first bias signal to the substrate support with the second power between the (c1) and the (c2), the fifth power being equal to or lower than the fourth power.

8. The etching method according to claim 7, wherein the (c) further includes (c4) forming the plasma by setting the power of the source RF signal to a sixth power, and supplying the first bias signal to the substrate support with the second power between the (c1) and the (c3), the sixth power being lower than the first power and higher than the fourth power.

9. The etching method according to claim 7, wherein the fourth power and the fifth power are each zero power.

10. The etching method according to claim 7, wherein the fifth power is lower than the fourth power, and the fifth power is zero power.

11. The etching method according to claim 1, wherein the first frequency is 60 MHz to 200 MHz.

12. The etching method according to claim 1, wherein a frequency of the first bias signal is 100 kHz to 800 kHz.

13. The etching method according to claim 1,
wherein in the (c1), a second bias RF signal is supplied to the substrate support with a seventh power, and the second bias RF signal has a second frequency lower than the first frequency, and
in the (c2), the second bias RF signal is supplied to the substrate support with an eighth power lower than the seventh power.

14. The etching method according to claim 13, wherein the second frequency is 3 MHz to 40 MHz.

15. The etching method according to claim 1, wherein the metal-containing gas is a gas including a tungsten-containing gas or a molybdenum-containing gas.

16. The etching method according to claim 15, wherein the tungsten-containing gas includes tungsten fluoride.

17. The etching method according to claim 1, wherein the processing gas includes a carbon-containing gas.

18. The etching method according to claim 17, wherein the carbon-containing gas is a fluorocarbon gas.

19. An etching method executed in a plasma processing apparatus including a chamber, the etching method comprising:
(a) controlling an electrostatic chuck to hold a substrate on a substrate support disposed in the chamber, the substrate including a first film and a second film, the first film containing at least one type selected from the group consisting of SiN, SiON, SiC, SiOC, and boron nitride, and the second film containing silicon and oxygen;
(b) supplying a processing gas including a metal-containing gas into the chamber; and
(c) while the (b) is being executed, selectively etching the second film with respect to the first film, the (c) including:
(c1) forming a plasma by setting a power of a source RF signal having a first frequency to a first power, and supplying a first bias signal to the substrate support with a second power, the first bias signal having a frequency that does not substantially contribute to the formation of the plasma, and
(c2) after the (c1), supplying the first bias signal to the substrate support with a third power higher than the second power.

20. A plasma processing apparatus comprising:
a chamber;
a substrate support disposed in the chamber and including an electrostatic chuck; and
controller circuitry,
wherein the controller circuitry is configured to execute:
(a) controlling the electrostatic chuck to hold a substrate on the substrate support, the substrate including a first film and a second film, the first film containing silicon and nitrogen, and the second film containing silicon and oxygen;
(b) supplying a processing gas including a metal-containing gas into the chamber; and
(c) while the (b) is being executed, selectively etching the second film with respect to the first film, the (c) including:
(c1) forming a plasma by setting a power of a source RF signal having a first frequency to a first power, and supplying a first bias signal to the substrate support with a second power, the first bias signal having a frequency that does not substantially contribute to the formation of the plasma, and
(c2) after the (c1), supplying the first bias signal to the substrate support with a third power higher than the second power.
